(19) United States
(12) Patent Application Publication
(10) Pub. No.: US 2009/0194238 A1
(43) Pub. Date: Aug. 6, 2009

(54) PLASMA PROCESSING APPARATUS

(75) Inventors: Kiyotaka Ishibashi, Hyogo (JP); Toshihisa Nozawa, Hyogo (JP); Shinya Nishimoto, Hyogo (JP); Shinji Komoto, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/361,066

(22) Filed: Jan. 28, 2009

(30) Foreign Application Priority Data
Feb. 1, 2008 (JP) 2008-023346

(51) Int. Cl. C23F 1/08; C23C 16/54

(52) U.S. Cl. 156/345.52; 118/723 R

(57) ABSTRACT

Provided is a plasma processing apparatus capable of easily processing a top surface of a mounting table to have a smooth shape, and also capable of preventing a temperature of a peripheral portion of a substrate from decreasing. A plasma processing apparatus 5 processes a substrate W in a processing vessel 20 by converting a processing gas, which is supplied into the processing vessel 20, into plasma, wherein a mounting table 21 for mounting the substrate W on a top surface thereof is installed in the processing vessel 20, and positioning pins 25 for positioning a peripheral portion of the substrate W are installed to be protruded in plural locations on the top surface of the mounting table 21, and the positioning pins 25 are inserted into recess portions 26 formed in the top surface of the mounting table 21.

### FIELD OF THE INVENTION

The present disclosure relates to a plasma processing apparatus for processing a substrate by using plasma.

### BACKGROUND OF THE INVENTION

Conventionally, in order to perform a film forming process or an etching process on a substrate such as a silicon wafer, there has been used, for example, a plasma processing apparatus which employs a microwave or a plasma processing apparatus which generates plasma in a processing chamber by applying a high frequency voltage between an upper electrode and a lower electrode. In such a plasma processing apparatus, it has been known that protrusions for positioning a peripheral portion of a substrate are formed at plural locations on a top surface of a mounting table installed in a processing chamber (See Patent Document 1).

[Patent Document 1] Japanese Patent Laid-open Publication No. 2000-260851

In the above-described plasma processing apparatus, for example, a substrate is attracted to a top surface of a mounting table by using an electrostatic chuck. In this manner, in case that the substrate is attracted to the top surface of the mounting table by using the electrostatic chuck, it is desirable that the top surface of the mounting table, which makes a close contact with a bottom surface of the substrate during the attraction, has a smooth shape as possible so as to prevent a damage of the bottom surface of the substrate and the like. However, if protrusions for positioning the substrate are formed on the top surface of the mounting table, it is difficult to perform a polishing process on the top surface of the mounting table because the protrusions serve as an obstacle. Therefore, there occurs a problem that it becomes difficult to process the top surface of the mounting table to have a smooth shape.

Meanwhile, there can be considered a method of positioning a substrate by installing a guide ring on a top surface of a mounting table, which has undergone a polishing process to have a smooth shape, and mounting the substrate at an inner side of the guide ring. However, in case of surrounding a peripheral portion of the substrate with the guide ring, since the temperature of the peripheral portion of the substrate decreases due to an influence of the guide ring during the process, there may occur another problem, for example, that the film forming rate on the peripheral portion of the substrate decreases when a film forming process is performed.

### BRIEF SUMMARY OF THE INVENTION

In view of the foregoing, there is provided a plasma processing apparatus capable of easily processing a top surface of a mounting table to have a smooth shape, and also capable of preventing a temperature of a peripheral portion of a substrate from decreasing.

To achieve the object of the present invention, in accordance with an embodiment of the present invention, there is provided a plasma processing apparatus for processing a substrate in a processing vessel by converting a processing gas, which is supplied into the processing vessel, into plasma, wherein a mounting table for mounting the substrate on a top surface thereof is installed in the processing vessel, positioning pins for positioning a peripheral portion of the substrate are installed to be protruded in plural locations on the top surface of the mounting table, and the positioning pins are inserted into recess portions formed in the top surface of the mounting table.

In this plasma processing apparatus, the positioning pins can be easily removed from the recess portions formed in the top surface of the mounting table. For this reason, it is possible to process the top surface of the mounting table to have a smooth shape with the positioning pins removed. Further, since there are only the positioning pins in the vicinity of the peripheral portion of the substrate mounted on the top surface of the mounting table, the temperature of the peripheral portion of the substrate can be prevented from being decreased.

In this plasma processing apparatus, the mounting table may have an electrode for an electrostatic chuck which attracts the substrate mounted on the top surface of the mounting table.

Further, when viewed from the top, a total area of the positioning pins may be equal to or less than 5% of an area within a 15 mm distance from the peripheral portion of the substrate mounted on the top surface of the mounting table.

Furthermore, an upper peripheral surface of the positioning pin may have a tapered shape which gradually becomes thinner toward an upper end thereof. In this case, it is possible that a lower peripheral surface of the positioning pin has a cylindrical shape, and an angled portion at a boundary between the upper peripheral surface and the lower peripheral surface is placed at a position lower than the top surface of the mounting table.

Moreover, an upper end of an inner peripheral surface of the recess portion may be formed to have a curved surface. Further, the recess portions may be formed in plural groups in the top surface of the mounting table so as to correspond to a plurality of wafers having different sizes.

In accordance with another embodiment of the present invention, there is provided a plasma processing apparatus for processing a substrate in a processing vessel by converting a processing gas, which is supplied into the processing vessel, into plasma, wherein a mounting table for mounting the substrate on a top surface thereof is installed in the processing vessel, a ring member, which is spaced apart from a peripheral portion of the substrate mounted on the top surface of the mounting table, is detachably mounted on a peripheral portion of the top surface of the mounting table, and positioning portions for positioning the peripheral portion of the substrate are protruded in plural locations at an inner periphery of the ring member.

The mounting table may have an electrode for an electrostatic chuck which attracts the substrate mounted on the top surface of the mounting table. Further, when viewed from the top, a total area of the positioning pins may be equal to or less than 5% of an area within a 15 mm distance from the peripheral portion of the substrate mounted on the top surface of the mounting table.

In accordance with the embodiments of the present invention, the top surface of the mounting table can be polished with the positioning pin or the ring member removed, and the top surface of the mounting table, which makes a close contact with the bottom surface of the substrate during the attraction, can be easily processed to have a smooth shape. In addition, when processing the substrate after mounting the substrate on the top surface of the mounting table, since there are only the positioning pins or the positioning portions in the vicinity of the peripheral portion of the substrate, it is possible to prevent the temperature of the peripheral portion of the substrate from being decreased.

### BRIEF DESCRIPTION OF THE DRAWINGS

The disclosure may best be understood by reference to the following description taken in conjunction with the following figures:

FIG. 1 is an explanatory diagram of a plasma processing system;

FIG. 2 is a longitudinal cross sectional view showing a schematic configuration of a plasma processing apparatus in accordance with an embodiment of the present invention;

FIG. 3 is a plane view of a mounting table;

FIG. 4 is an explanatory diagram of a recess portion and a positioning pin;

FIG. 5 is an explanatory diagram showing the positioning pin tilted in the recess portion;

FIG. 6 is an explanatory diagram of a heat transfer among a mounting table, a guide ring and a transmitting window;

FIG. 7 is a graph showing a comparison of film forming rates at a peripheral portion of a wafer between a case in which the guide ring is disposed to make a close contact with the peripheral portion of the wafer and a case in which the guide ring is disposed to be spaced apart 15 mm from the peripheral portion of the wafer;

FIG. 8 is an explanatory diagram of a heat transfer among a mounting table, a positioning pin and a transmitting window;

FIG. 9 is a graph showing a relationship between an area ratio (buried surface area/protruded surface area) and a temperature of the positioning pin;

FIG. 10 is an explanatory diagram showing the positioning pin and the recess portion in accordance with an embodiment in which upper ends of an inner peripheral surface of the recess portion are formed to have a curved surface;

FIG. 11 is a plane view of a mounting table in accordance with an embodiment in which plural groups of recess portions are formed in a top surface of the mounting table;

FIG. 12 is an explanatory diagram showing an embodiment of positioning the peripheral portion of the wafer by using a ring member having a plurality of positioning portions at an inner periphery thereof; and

FIG. 13 is a cross sectional view taken along line X-X of FIG. 12.

### DETAILED DESCRIPTION OF THE INVENTION

Hereinafter, embodiments of the present invention will be described in detail with reference to the accompanying drawings. In addition, through the whole documents, like reference numerals denote like parts having substantially identical functions and configurations, so that redundant description thereof may be omitted.

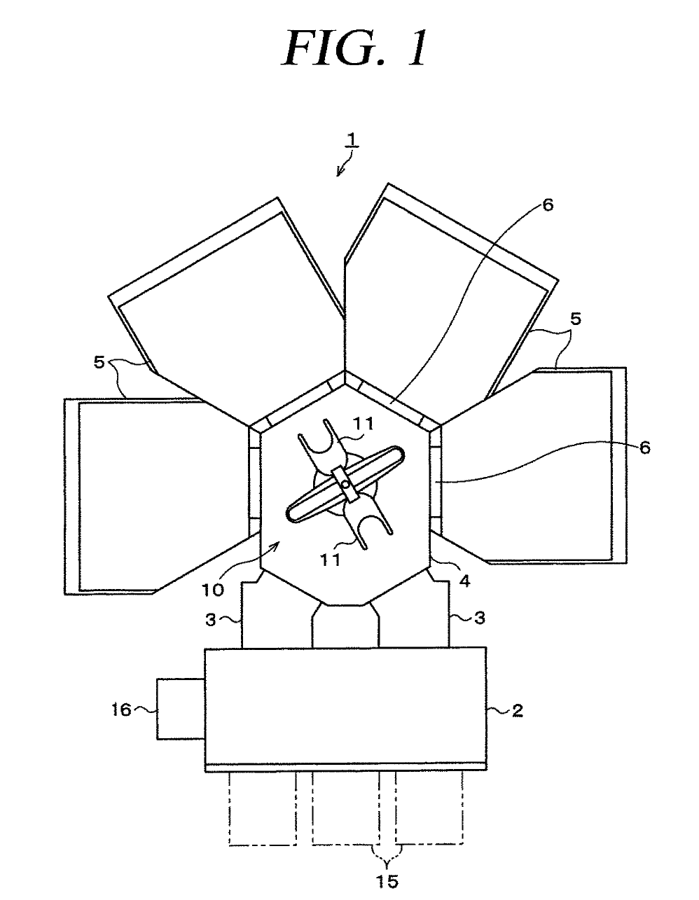

FIG. 1 is a plane view of a plasma processing system 1 provided with plasma processing apparatuses 5 in accordance with the embodiment of the present invention. The plasma processing system 1 includes a loading/unloading unit 2 for loading or unloading a wafer W serving as a substrate into or from the plasma processing system 1; two load lock chambers 3 installed adjacent to the loading/unloading unit 2; a transfer chamber 4 installed adjacent to each of the load lock chambers 3; and the plural plasma processing apparatuses 5 arranged around the transfer chamber 4. Gate valves 6 are installed between each of the plasma processing apparatuses 5 and the transfer chamber 4.

Installed in the transfer chamber 4 is a transfer mechanism 10 which loads and unloads the wafer W between the load lock chamber 3 and each of the plasma processing apparatuses 5. The transfer mechanism 10 has a pair of transfer arms 11 for supporting the wafer W. Inside of the transfer chamber 4 can be vacuum-exhausted. That is, by turning the inside of the transfer chamber 4 into a vacuum state, the wafer W taken out of the load lock chamber 3 can be transferred to the respective plasma processing apparatuses 5, and the wafer W taken out of the respective plasma processing apparatuses 5 can be returned to the load lock chamber 3. Therefore, it is possible to load and unload the wafer W while the inside of each plasma processing apparatus 5 is maintained in a vacuum state.

Cassettes 15 are disposed adjacent to the loading/unloading unit 2, and the wafer W taken out of the cassettes 15 by the loading/unloading unit 2 is delivered to the load lock chamber 3. Further, the wafer W taken out of the load lock chamber 3 by the loading/unloading unit 2 is returned to the cassettes 15. Installed at a side of the loading/unloading unit 2 is an alignment mechanism 16 for positioning the wafer W.

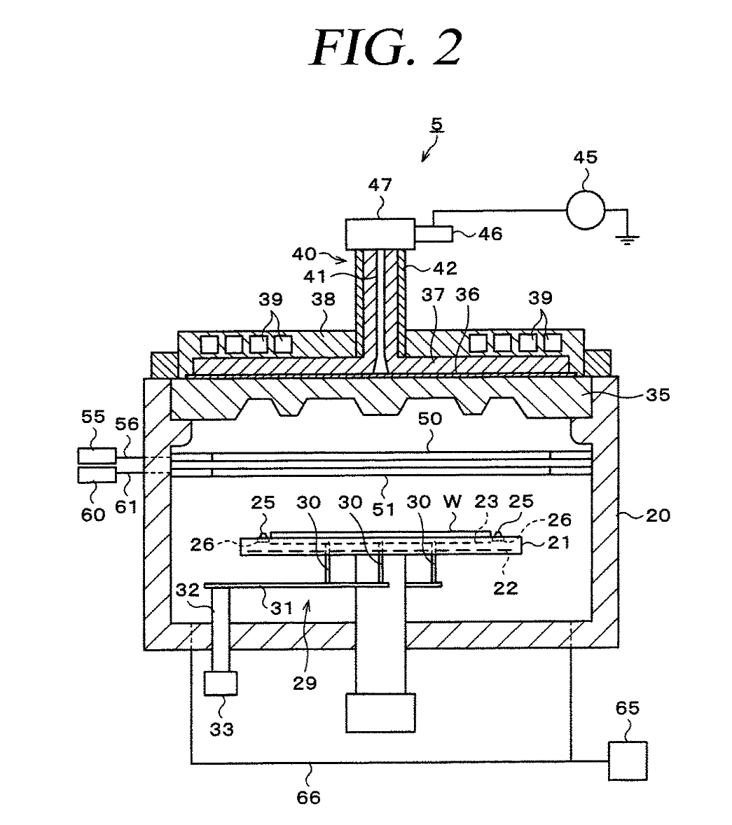

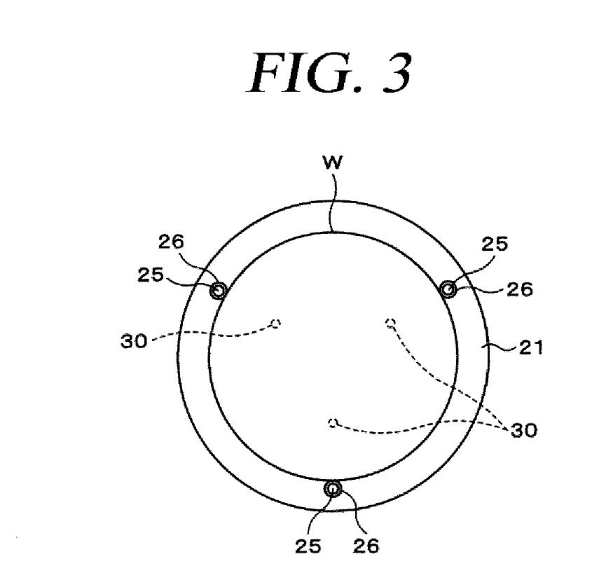

FIG. 2 is a longitudinal cross sectional view showing a schematic configuration of the plasma processing apparatus 5 in accordance with the embodiment of the present invention. FIG. 3 is a plane view of a mounting table 21 provided in the plasma processing apparatus 5.

The plasma processing apparatus 5 includes a processing vessel 20 of a cylindrical shape, which is made of, for example, aluminum and has an opening in a top portion thereof and also has a bottom portion. As will be described later, a plasma process is performed on the wafer W inside the processing vessel 20. The processing vessel 20 is electrically grounded.

At the bottom portion within the processing vessel 20, installed is a mounting table (susceptor) 21 of a cylindrical shape which mounts the wafer W on a top surface thereof. The mounting table 21 is made of, for example, aluminum nitride, and has a temperature control mechanism 22 such as a heater or the like therein. By the temperature control mechanism 22, the wafer W on the mounting table 21 can be controlled to have a predetermined temperature.

An electrode 23 for an electrostatic chuck (ESC) is embedded in the mounting table 21. When the wafer W is mounted on the top surface of the mounting table 21, a voltage is applied to the electrode 23 so as to perform an accurate temperature control by the temperature control mechanism 22. Accordingly, positive and negative charges are generated between the wafer W and the mounting table 21. Then, by a Johnson-Rahbek force applied between the wafer W and the mounting table 21, the wafer W is securely attracted to the top surface of the mounting table 21.

In this manner, since an entire bottom surface of the wafer W is closely held and mounted on the top surface of the mounting table 21, it is desirable that the top surface of the mounting table 21, which makes a close contact with the bottom surface of the wafer W during the attraction, has a smooth shape as possible. For this reason, the top surface of the mounting table 21 is processed to have a smooth shape by performing a polishing process.

On the top surface of the mounting table 21, a plurality of positioning pins 25 is installed to protrude upward from the top surface of the mounting table 21. In this example, three positioning pins 25 are installed on the top surface of the mounting table 21. Each of the positioning pins 25 has an approximately cylindrical shape, and is inserted into a recess portion 26 of a cylindrical shape formed in the top surface of the mounting table 21 so that the positioning pins 25 are maintained at predetermined locations in the top surface of the mounting table 21.

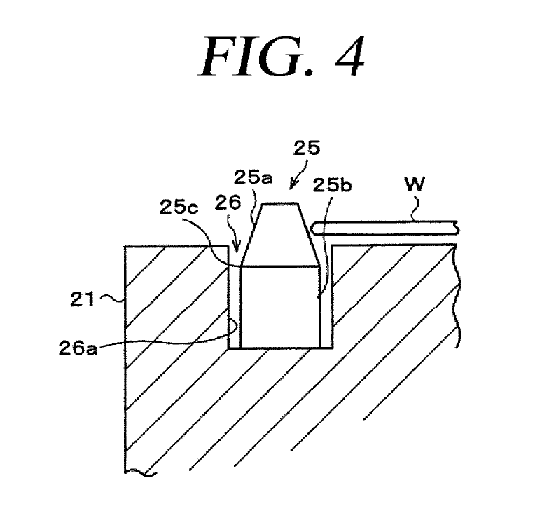

As shown in FIG. 4, an upper peripheral surface 25a of the positioning pin 25 has a tapered shape (i.e., gradually becoming thinner toward an upper end thereof), and a lower peripheral surface 25b of the positioning pin 25 has a cylindrical shape with a constant diameter. An inclined angle (an inclined angle from the horizontal) of the upper peripheral surface 25a is, for example, about 45 to 80 degrees. An inner peripheral surface 26a of the recess portion 26 has a cylindrical shape with a constant diameter greater than the diameter of the lower peripheral surface 25b of the positioning pin 25. Although the positioning pin 25 is maintained at the top surface of the mounting table 21 by inserting a lower half portion of the positioning pin 25 into the recess portion 26, the positioning pin 25 can be easily removed from the top surface of the mounting table 21 by upwardly pulling out the positioning pin 25 from the recess portion 26 because the diameter of the lower peripheral surface 25b of the positioning pin 25 is smaller than the diameter of the inner peripheral surface 26a of the recess portion 26.

In the peripheral surface of the positioning pin 25, an angled portion 25c at a boundary between the upper peripheral surface 25a and the lower peripheral surface 25b, is installed at a position lower than the top surface of the mounting table 21.

Installed below the mounting table 21 is an elevating mechanism 29 for appropriately elevating the wafer W mounted on the mounting table 21. The elevating mechanism 29 is configured so that three elevating pins 30 capable of protruding toward the top surface of the mounting table 21 are installed vertically on a top surface of a plate 31. The plate 31 of the elevating mechanism 29 is supported on an upper end of a supporting column 32 penetrating the bottom portion of the processing vessel 20. Installed at a lower end of the supporting column 32 is an elevating device 33 disposed outside the processing vessel 20. By the operation of the elevating device 33, the three elevating pins 30 penetrating the mounting table 21 move up and down, so that a state in which an upper end of the elevating pin 30 is protruded upward from the top surface of the mounting table 21 alternates with a state in which the upper end of the elevating pin 30 is pulled into the inside of the mounting table 21.

The wafer W, which is loaded above the mounting table 21 while being carried by the transfer arm 11, is lifted up from the transfer arm 11 by the three elevating pins 30 of the elevating mechanism 29, so that the wafer W is received by the elevating pins 30. Then, after the transfer arm 11 is withdrawn, the elevating pins 30 are descended so that the wafer W is mounted on the top surface of the mounting table 21.

Then, when the wafer W is mounted on the top surface of the mounting table 21 by descending the elevating pins 30, a peripheral portion of the wafer W is guided onto the upper peripheral surface 25a of the positioning pin 25, which is formed in the tapered shape, with the descent of the elevating pins 30, so that the wafer W is positioned to be mounted on the center of the top surface of the mounting table 21.

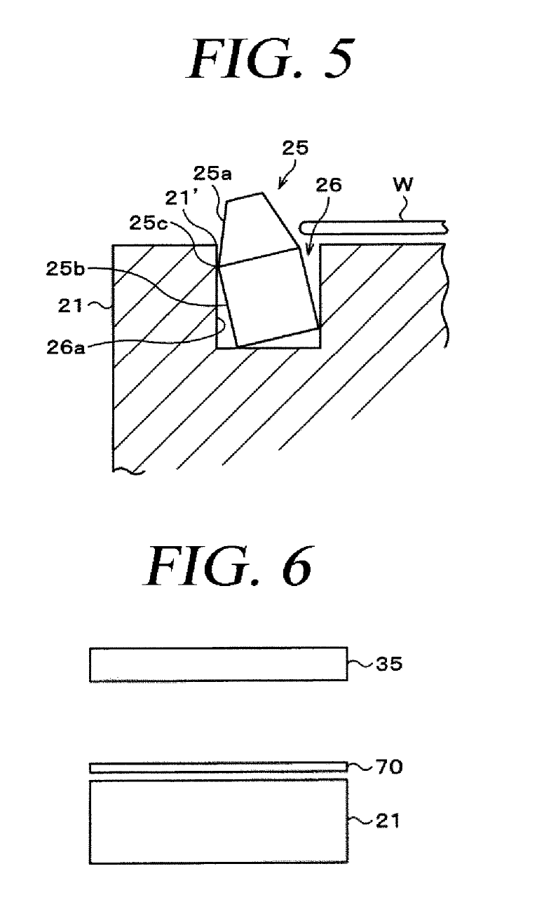

Further, when positioning the wafer W in the above-described manner, since the peripheral portion of the wafer W makes contact with the upper peripheral surface 25a of the positioning pin 25, there is a likelihood that the positioning pin 25 is pushed to the side and tilted within the recess portion 26. As described above, since the angled portion 25c at the peripheral surface of the positioning pin 25 is installed at a position lower than the top surface of the mounting table 21, when the positioning pin 25 is tilted in the recess portion 26 as mentioned above, the angled portion 25c of the peripheral surface of the positioning pin 25 is brought into contact with the inner peripheral surface 26a of the recess portion 26, as illustrated in FIG. 5. In this manner, even if the positioning pin 25 is tilted in the recess portion 26, an angled portion 21′ between an upper end of the recess portion 26 and the top surface of the mounting table 21 does not make contact with the peripheral surface of the positioning pin 25, thereby preventing a damage of the positioning pin 25.

A transmitting window 35 made of, for example, a dielectric material such as quartz is installed at the opening in the top part of the processing vessel 20 via an O ring to ensure the airtightness. The transmitting window 35 has an approximately disc shape. Instead of the quartz, other dielectric material, for example, ceramics such as Al₂O₃, AlN and the like can be employed.

Installed above the transmitting window 35 is a planar antenna member, for example, a radial line slot antenna 36 of a circular plate shape. The radial line slot antenna 36 is made of a thin circular plate of copper plated or coated with a conductive material such as Ag, Au or the like. In the radial line slot antenna 36, a plurality of slits which transmit a microwave therethrough are arranged in, for example, a spiral or concentric shape.

On a top surface of the radial line slot antenna 36, there is disposed a slow wave plate 37 for shortening a wavelength of the microwave. The slow wave plate 37 is covered by a conductive cover 38. Heat transfer medium paths 39 of a circular ring shape are installed in the cover 38, and by heat transfer mediums flowing through the heat transfer medium paths 39, the cover 38 and the transmitting window 35 are maintained at a predetermined temperature.

A coaxial waveguide 40 is connected to the center of the cover 38. The coaxial waveguide 40 includes an inner conductor 41 and an outer tube 42. The inner conductor 41 is connected to the radial line slot antenna 36. The inner conductor 41's one side adjacent to the radial line slot antenna 36 is formed in a cone shape, so that the microwave is efficiently propagated to the radial line slot antenna 36.

A microwave of, e.g., 2.45 GHz generated from a microwave supplying unit 45 is radiated to the transmitting window 35 via a rectangular waveguide 46, a mode converter 47, the coaxial waveguide 40, the slow wave plate 37 and the radial line slot antenna 36. Further, an electric field is formed at a bottom surface of the transmitting window 35 by a microwave energy, and plasma is generated in the processing vessel 20.

In the processing vessel 20, an upper shower plate 50 and a lower shower plate 51 serving as a gas supplying unit are installed above the mounting table 21. The upper shower plate 50 and the lower shower plate 51 are configured as a hollow tube made of, for example, a quartz tube. Although not illustrated, arranged in the upper shower plate 50 and the lower shower plate 51 is a multiplicity of openings for supplying a gas to the wafer W on the mounting table 21.

The upper shower plate 50 is connected to a plasma generating gas supply source 55, which is placed at the outside of the processing vessel 20, via a pipe 56. Stored in the plasma generating gas supply source 55 is, e.g., nitrogen, Ar, oxygen or the like serving as a plasma generating gas. The plasma generating gas is introduced into the upper shower plate 50 from the plasma generating gas supply source 55 via the pipe 56, so that the plasma generating gas is supplied into the processing vessel 20 at a uniformly distributed state.

The lower shower plate 51 is connected to a processing gas supply source 60, which is placed at the outside of the processing vessel 20, via a pipe 61. Stored in the processing gas supply source 60 is, e.g., TEOS or the like serving as a processing gas. The processing gas is introduced into the lower shower plate 51 from the processing gas supply source 60 via the pipe 61, and the processing gas is supplied into the processing vessel 20 at a uniformly distributed state.

At the bottom portion of the processing vessel 20 is connected a gas exhaust pipe 66 for exhausting an atmosphere in the processing vessel 20 by using a gas exhaust unit 65 such as a vacuum pump.

Hereinafter, the operation of the plasma processing system 1 having the above-mentioned configuration will be described. Further, as an example of the plasma process, there will be described an example of forming an insulating film (SiO₂ film) on a surface (a top surface) of the wafer W by using Ar and oxygen as the plasma generating gas and using TEOS as the processing gas.

First, after adjusting the position of the wafer W taken out of the cassette 15 in the alignment mechanism 16, the wafer W is delivered to the load lock chamber 3 from the loading/unloading unit 2. Then, while the load lock chamber 3 and the transfer chamber 4 are maintained in a vacuum state, the wafer W is taken out of the load lock chamber 3 by the transfer arm 11 of the transfer mechanism 10, and then the wafer W is loaded into the plasma processing apparatus 5.

The wafer W is loaded into the processing vessel 20 of the plasma processing apparatus 5 and is moved to above the mounting table 21 while being carried on a top surface of the transfer arm 11. Thereafter, by the operation of the elevating device 33, the three elevating pins 30 of the elevating mechanism 29 are elevated so as to push the wafer W supported by the transfer arm 11 upward, so that the wafer W is lifted above the transfer arm 11. In this manner, the wafer W is transferred to the three elevating pins 30 of the elevating mechanism 29, and then the transfer arm 11 is withdrawn from above the mounting table 21, and then the transfer arm 11 is returned to the transfer chamber 4. After the withdrawal of the transfer arm 11, the three elevating pins 30 are descended by the operation of the elevating device 33 and the wafer W is mounted on the top surface of the mounting table 21.

When the wafer W is mounted on the top surface of the mounting table 21, the peripheral portion of the wafer W is guided onto the upper peripheral surface 25a of the positioning pin 25, which is formed in the tapered shape, with the descent of the elevating pins 30, so that the wafer W is positioned to be mounted on the center of the top surface of the mounting table 21. In this case, as described above with reference to FIG. 5, since the peripheral portion of the wafer W makes contact with the upper peripheral surface 25a of the positioning pin 25, there is a likelihood that the positioning pin 25 is pushed to the side and tilted in the recess portion 26. However, since the angled portion 25c at the peripheral surface of the positioning pin 25 is installed at a position lower than the top surface of the mounting table 21, the angled portion 21′ between the upper end of the recess portion 26 and the top surface of the mounting table 21 does not make contact with the peripheral surface of the positioning pin 25, thereby preventing a damage of the positioning pin 25.

In this manner, if the wafer W is mounted on the mounting table 21, the inside of the processing vessel 20 becomes an airtight state, and the gas is exhausted through the gas exhaust pipe 66 so that the inside of the processing vessel 20 is depressurized. Further, the plasma generating gas (Ar, oxygen) is supplied into the processing vessel 20 from the upper shower plate 50, and the processing gas (TEOS) for the plasma film formation is supplied into the processing vessel 20 from the lower shower plate 51. In addition, the electric field is generated at the bottom surface of the transmitting window 35 by the operation of the microwave supplying unit 45, and then the plasma generating gas is converted into plasma and also the processing gas is converted into plasma, so that a film forming process is performed on the wafer W by active species generated at this time.

Moreover, during the plasma process, a voltage is applied to the electrode 23 embedded in the mounting table 21, so that the wafer W is securely attracted to the top surface of the mounting table 21. Further, by bringing the entire bottom surface of the wafer W into a close contact with the top surface of the mounting table 21 as described above, the temperature control by the temperature control mechanism 22 is accurately performed.

After the film forming process was performed for a certain period of time, the operation of the microwave supplying unit 45 and the supply of the processing gas into the processing vessel 20 are stopped. Thereafter, the three elevating pins 30 are elevated by the operation of the elevating device 33 of the elevating mechanism 29, and the wafer W mounted on the top surface of the mounting table 21 is lifted above the mounting table 21. Then, the transfer arm 11 of the transfer mechanism 10 is transferred into the processing vessel 20, and the transfer arm 11 approaches above the mounting table 21.

After the transfer arm 11 approached above the mounting table 21, the three elevating pins 30 are descended by the operation of the elevating device 33. As a result, the wafer W is loaded onto the transfer arm 11. Then, the wafer W loaded onto the transfer arm 11 is unloaded from the plasma processing apparatus 5 and returned to the load lock chamber 3. The wafer W returned to the load lock chamber 3 in this manner is then returned to the cassette 15 via the loading/unloading unit 2.

In this plasma processing system 1, the positioning pins 25 can be easily removed by pulling them out upward from the top surface of the mounting table 21 installed in the processing vessel 20 of the plasma processing apparatus 5. Therefore, a polishing process can be performed on the top surface of the mounting table 21 with the positioning pins 25 removed, so that the top surface of the mounting table 21, which makes a close contact with the bottom surface of the wafer W during the attraction, can be easily processed to have a smooth shape. Further, when performing the plasma process on the wafer W after mounting it on the top surface of the mounting table 21, there are only the positioning pins 25 in the vicinity of the peripheral portion of the wafer W, so that it is also possible to prevent the temperature of the peripheral portion of the wafer W from being decreased. As a result, the efficiency of the plasma process is enhanced and the productivity is improved.

Here, as shown in FIG. 6, in case that a conventional guide ring 70 is mounted on the top surface of the mounting table 21, examined was a heat transfer among the mounting table 21, the guide ring 70 and the transmitting window 35. It will be assumed that T₂₁, T₃₅ and T₇₀ represent temperatures of the mounting table 21, the transmitting window 35 and the guide ring 70, respectively. In an equilibrium state, a heat transferred from the mounting table 21 to the guide ring 70 is the same as a heat transferred from the guide ring 70 to the transmitting window 35, so that an equation (1) as follows is satisfied.

σ(T₂₁⁴−T₇₀⁴)/(1/ε₇₀+1/ε₂₁−1)=σ(T₇₀⁴−T₃₅⁴)/(1/ε₃₅+1/ε₇₀−1) . . . (1)

Here, σ represents a Stefan-Boltzmann constant, ε₂₁ represents an emissivity of the mounting table 21, ε₃₅ represents an emissivity of the transmitting window 35 and ε₇₀ represents an emissivity of the guide ring 70.

For instance, in case that materials of the mounting table 21, the transmitting window 35 and the guide ring 70 are AlN (ε₂₁=0.9), quartz (ε₃₅=0.9) and alumina (ε₇₀=0.9), respectively, if the temperature T₂₁ of the mounting table 21 is 380° C. and the temperature T₃₅ of the transmitting window 35 is 200° C., the temperature T₇₀ of the guide ring 70 becomes about 310° C. by the equation (1), so that there occurs a temperature difference of about 70° C. between the mounting table 21 and the guide ring 70.

In this manner, in case that the guide ring 70 is disposed to make a close contact with the peripheral portion of the wafer W mounted on the top surface of the mounting table 21, the temperature difference of about 70° C. is incurred between the mounting table 21 and the guide ring 70 so that the temperature of the peripheral portion of the wafer W is decreased, thereby exerting a bad influence on the plasma process. For instance, in case of a CFx film forming plasma process using Ar/C₅F₈ as a processing gas, a film forming precursor is apt to be deposited on a surface of a material having a lower temperature. Accordingly, between a high temperature material and a low temperature material, a film forming precursor in a gas phase at a surface of the low temperature material is readily absorbed into a surface of the material whereby the density of the gas phase is lowered. If the temperature of the peripheral portion of the wafer W decreases, the film forming precursor in the vicinity of the peripheral portion of the wafer W also decreases.

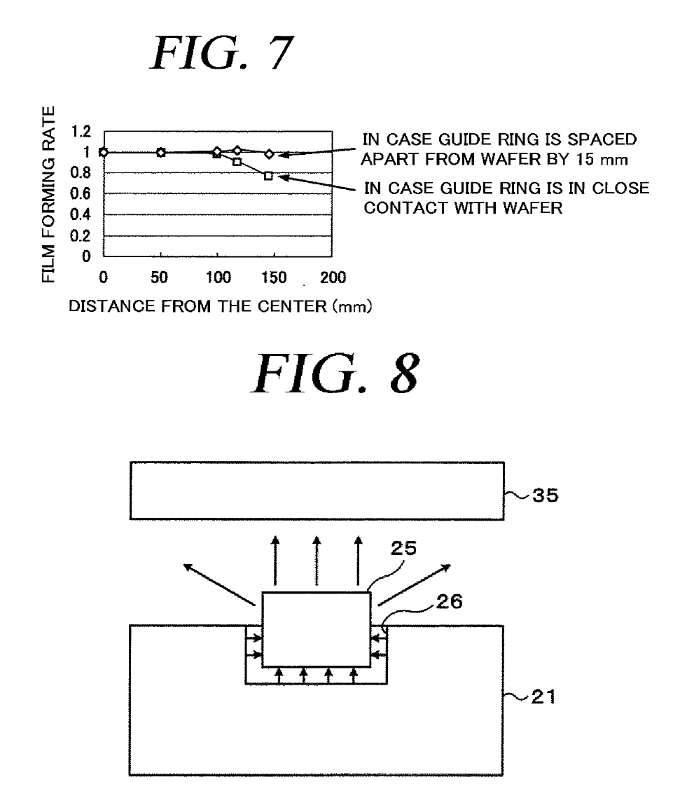

FIG. 7 is a graph showing a comparison of film forming rates at the peripheral portion of the wafer W between a case in which the guide ring 70 is disposed to make a close contact with the peripheral portion of the wafer W and a case in which the guide ring 70 is disposed to be spaced apart 15 mm from the peripheral portion of the wafer W, under the condition when there is almost no temperature difference between the wafer W and the mounting table 21 by bringing the wafer W into a close contact with the top surface of the mounting table 21 by using the electrostatic chuck. In addition, the comparison is carried out on the CFx film forming plasma process using Ar/C₅F₈ as a processing gas.

According to the knowledge of the inventors of the present invention, when viewed from the top, if a total area of the positioning pins 25 is equal to or less than 5% of an area within a 15 mm distance from the peripheral portion of the wafer W mounted on the top surface of the mounting table 21, the temperature of the peripheral portion is prevented from being decreased. Therefore, it is proved that the temperature of the entire wafer W can be maintained uniform, and the film can be formed over the entire surface of the wafer W at a uniform rate.

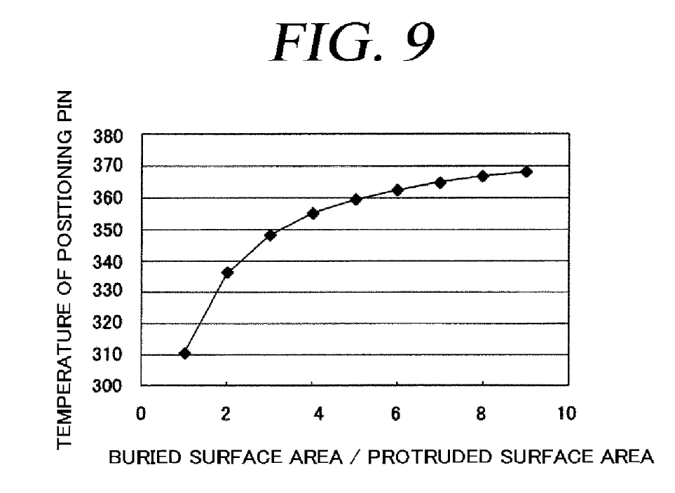

Thereafter, there was examined a temperature of the positioning pin 25 inserted into the recess portion 26 formed in the top surface of the mounting table 21, as shown in FIG. 8. For example, in case that a material of the positioning pin 25 is alumina, shown in FIG. 9 is a relationship between a temperature of the positioning pin 25 and a ratio (buried surface area/protruded surface area) of an area of the positioning pin 25 (a buried surface area), which is facing an inner surface of the recess portion 26, to an area of the positioning pin 25 (a protruded surface area), which is protruded from the top surface of the mounting table 21. In case that the material of the positioning pin 25 is alumina, if the ratio (buried surface area/protruded surface area) is set to be 5 or more, the temperature difference between the mounting table 21 and the positioning pin 25 can be 20° C. or less, so that it is possible to satisfy the required specification. Further, if the material of the positioning pin 25 is Si having a high resistance, the high resistive Si has an emissivity smaller than that of the alumina, so that it is difficult for a heat to be transferred outside. Therefore, if the ratio (buried surface area/protruded surface area) is set to be 2 or more, the temperature difference between the mounting table 21 and the positioning pin 25 can be 20° C. or less.

Although the above description of the present invention has been provided for the purpose of illustration, it would be understood by those skilled in the art that various changes and modifications may be made without changing technical conception and essential features of the present invention. Thus, it is clear that the above-described embodiments are illustrative in all aspects and do not limit the present invention.

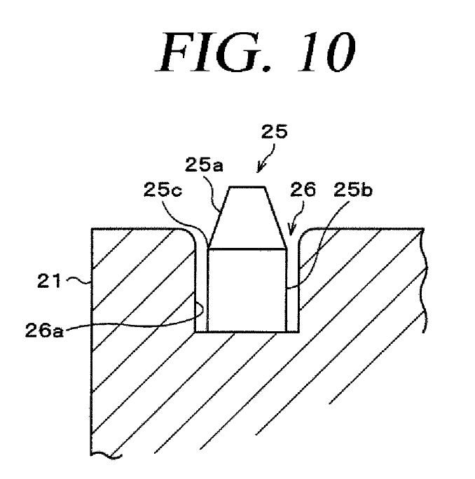

For example, as described in FIG. 5, when positioning the wafer W, since the peripheral portion of the wafer W makes contact with the upper peripheral surface 25a of the positioning pin 25, there is a likelihood that the positioning pin 25 is pushed to the side and tilted in the recess portion 26. Therefore, as shown in FIG. 10, an upper end of the inner peripheral surface of the recess portion 26 may be formed to have a curved surface. In this manner, the damage of the positioning pin 25 can be prevented more securely.

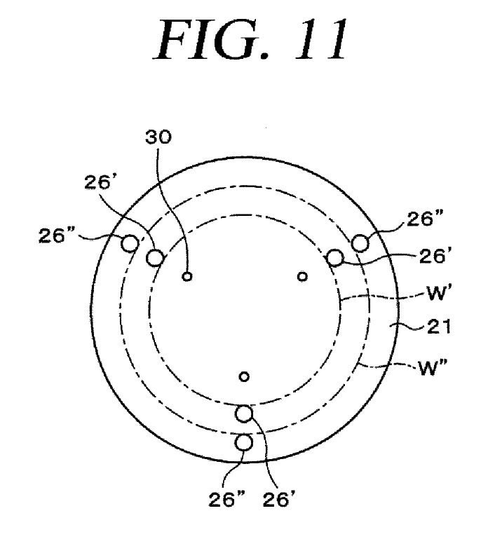

Further, the recess portions 26 may be formed in plural groups in the top surface of the mounting table 21 so as to correspond to a plurality of wafers W having different sizes. For example, as shown in FIG. 11, recess portions 26′ for positioning an 8-inch wafer W′ are arranged in a concentric circular shape at an inner portion in the top surface of the mounting table 21, while recess portions 26″ for positioning a 12-inch wafer W″ are arranged in a concentric circular shape at an outer portion in the top surface of the mounting table 21. In this case, if the positioning pins 25 are inserted into the recess portions 26′ at the inner portion, the 8-inch wafer W′ can be positioned, and if the positioning pins 25 are inserted into the recess portions 26″ at the outer portion, the 12-inch wafer W″ can be positioned.

Furthermore, the example has been described in case that the peripheral portion of the wafer W is guided by three positioning pins 25 at the top surface of the mounting table 21, but the number of positioning pins 25 is not limited thereto, so the peripheral portion of the wafer W may be guided by using four or more positioning pins 25.

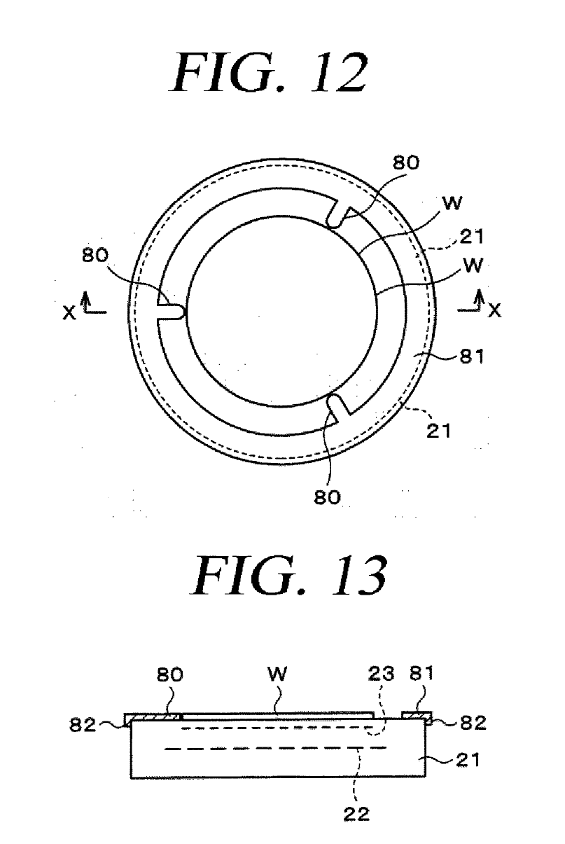

FIG. 12 shows an embodiment of positioning the peripheral portion of the wafer W to be mounted on the top surface of the mounting table 21 by using a ring member 81 having a plurality of positioning portions 80 at an inner periphery thereof. FIG. 13 is a cross sectional view taken along line X-X of FIG. 12.

Installed at an outer periphery of the ring member 81 is a cover portion 82 surrounding upper part of the peripheral surface of the mounting table 21. The ring member 81 is detachably mounted on the top surface of the mounting table 21 formed in a plane. At this time, by covering the upper part of the peripheral surface of the mounting table 21 with the cover portion 82, the ring member 81 can always be installed at a constant location on the top surface of the mounting table 21. At the inner periphery of the ring member 81, the positioning portions 80 for positioning the peripheral portion of the wafer W to be mounted on the top surface of the mounting table 21 are installed in plural locations. Further, in the illustrated example, the positioning portions 80 are installed at three locations. In this case, when viewed from the top, a total area of the positioning portions 80 is equal to or less than 5% of an area within a 20 mm distance from the peripheral portion of the wafer W mounted on the top surface of the mounting table 21.

Likewise, the peripheral portion of the wafer W can be positioned by using the positioning portions 80 installed at the inner periphery of the ring member 81. In addition, the ring member 81 can be easily removed from the top surface of the mounting table 21. For this reason, the top surface of the mounting table 21 can be polished with the ring member 81 removed, so that the top surface of the mounting table 21, which makes a close contact with the bottom surface of the wafer W during the attraction, can be easily processed to have a smooth shape. Further, when performing the plasma process on the wafer W after mounting it on the top surface of the mounting table 21, there are only the positioning portions 80 in the vicinity of the peripheral portion of the wafer W, so that it is also possible to prevent the temperature of the peripheral portion of the wafer W from being decreased. As a result, the efficiency of the plasma process is enhanced and the productivity is improved.

Further, in the above-described embodiments, the plasma process employing the microwave has been described as an example, but it is not limited thereto, and it is obvious that the present invention is applicable to a plasma process employing a high frequency voltage. Furthermore, in the above-described embodiments, although the present invention is applied to the plasma process which performs the film forming process, the present invention is also applicable to a plasma process which performs a substrate process, e.g., an etching process besides the film forming process. Further, a substrate to be processed by the plasma process in accordance with the present invention may be a semiconductor wafer, an organic EL substrate, an FPD (Flat Panel Display) substrate or the like.

The present invention may be applied to the plasma process for processing the substrate by generating plasma in the processing vessel.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A plasma processing apparatus for processing a substrate in a processing vessel by converting a processing gas, which is supplied into the processing vessel, into plasma,
wherein a mounting table for mounting the substrate on a top surface thereof is installed in the processing vessel,
positioning pins for positioning a peripheral portion of the substrate are installed to be protruded in plural locations on the top surface of the mounting table, and
the positioning pins are inserted into recess portions formed in the top surface of the mounting table.

2. The plasma processing apparatus of claim 1, wherein the mounting table has an electrode for an electrostatic chuck which attracts the substrate mounted on the top surface of the mounting table.

3. The plasma processing apparatus of claim 1, wherein, when viewed from the top, a total area of the positioning pins is equal to or less than 5% of an area within a 15 mm distance from the peripheral portion of the substrate mounted on the top surface of the mounting table.

4. The plasma processing apparatus of claim 1, wherein an upper peripheral surface of the positioning pin has a tapered shape which gradually becomes thinner toward an upper end thereof.

5. The plasma processing apparatus of claim 4, wherein a lower peripheral surface of the positioning pin has a cylindrical shape, and
an angled portion at a boundary between the upper peripheral surface and the lower peripheral surface is placed at a position lower than the top surface of the mounting table.

6. The plasma processing apparatus of claim 1, wherein an upper end of an inner peripheral surface of the recess portion is formed to have a curved surface.

7. The plasma processing apparatus of claim 1, wherein the recess portions are formed in plural groups in the top surface of the mounting table so as to correspond to a plurality of wafers having different sizes.

8. A plasma processing apparatus for processing a substrate in a processing vessel by converting a processing gas, which is supplied into the processing vessel, into plasma,
wherein a mounting table for mounting the substrate on a top surface thereof is installed in the processing vessel,
a ring member, which is spaced apart from a peripheral portion of the substrate mounted on the top surface of the mounting table, is detachably mounted on a peripheral portion of the top surface of the mounting table, and
positioning portions for positioning the peripheral portion of the substrate are protruded in plural locations at an inner periphery of the ring member.

9. The plasma processing apparatus of claim 8, wherein the mounting table has an electrode for an electrostatic chuck which attracts the substrate mounted on the top surface of the mounting table.

10. The plasma processing apparatus of claim 8, wherein, when viewed from the top, a total area of the positioning pins is equal to or less than 5% of an area within a 15 mm distance from the peripheral portion of the substrate mounted on the top surface of the mounting table.
